(19) United States
(12) Patent Application Publication
(10) Pub. No.: US 2005/0141323 A1
(43) Pub. Date: Jun. 30, 2005

(54) Semiconductor memory device for reducing lay-out area

(76) Inventor: Young-Bo Shim, Ichon-shi (KR)

Correspondence Address: JACOBSON HOLMAN PLLC, 400 SEVENTH STREET N.W., SUITE 600, WASHINGTON, DC, 20004, US

(21) Appl. No.: 10/875,620

(22) Filed: Jun. 25, 2004

(30) Foreign Application Priority Data
Dec. 29, 2003 (KR) 2003-98498

(51) Int. Cl. G11C 11/34

(52) U.S. Cl. 365/230.03

(57) ABSTRACT

A semiconductor memory device having a number of banks, reduces circuit area of a Y controlling unit for decoding a column address. The circuit area for a circuit block for decoding the column address in the memory device can be significantly reduced so that the memory device can be integrated even highly. The semiconductor memory device1 includes a first bank and a second bank, a pre-decoder for pre-decoding a column address, a first main decoder for decoding the output signal from the pre-decoder to select a bit line of the first bank, and a second main decoder for decoding the output signal from the pre-decoder to select a bit line of the second bank.

### FIELD OF THE INVENTION

The present invention relates to a semiconductor memory device; and, more particularly, to a semiconductor memory device for reducing lay-out area.

### BACKGROUND OF THE INVENTION

FIG. 1 provides a block diagram of a semiconductor memory device having four banks.

Referring to FIG. 1, the semiconductor memory device includes four banks 11, 12, 21, 22, 31, 32, 41, 42, each bank being divided into two blocks. The bank is divided into two regions in order to output two data simultaneously from the bank to an external device during one data access as in a DDR memory.

Each of the banks includes an X controlling unit 12, 14, 23, 24, 33, 34, 43, 44 for decodes a row address to activate one of a number of word lines in the bank, and a Y controlling unit 15, 16, 25, 26, 35, 36, 45, 46 for decoding a column address to activate one of a number of bit lines in the bank.

For efficient the arrangement of memory cells, elements of one bank could be arranged physically apart from each other.

FIG. 2 provides a block diagram of a semiconductor memory device having four banks, in which the banks are arranged differently from the banks in FIG. 1.

In FIG. 2, the bank is divided into four regions for the efficient arrangement of the respective X controlling units and the Y controlling units and the efficient data access.

FIG. 3 describes a block diagram of the Y controlling units 15, 16, 35, 36 for the bank bank0 and the bank bank1.

The Y controlling unit 15, 16 on the right side in FIG. 3 is the Y controlling unit for the bank bank0 and the Y controlling unit 35, 36 on the left side in FIG. 3 is the Y controlling unit for the bank bank1.

First, the Y controlling unit 15, 16 for the bank bank0 includes a column address controlling unit 10, a first and a second pre-decoders 15_1, 16_1, and a first and a second main decoders 15_1, 16_2. The Y controlling unit 35, 36 for the bank bank1 includes a column address controlling unit 13, a first and a second pre-decoders 35_1, 36_1, and a first and a second main decoders 35_{—‘1, 36}_2.

The column address controlling unit 10 receives and counts a bank address b<0> and column addresses y<0:11> from a command to generate inner column addresses byac<11:3>, byac_e<1:2>, byac_o<1:2> and transfers them to the first and the second pre-decoders 15_1, 16_1. At this point, the column address controlling unit 10 shifts them by two clocks in write command execution while it does not shift them in read command execution, and adjusts the outputted address depending on information about data type, e.g., sequence or interleave mode type, or burst length for the current command.

The first pre-decoder 15_1 includes 4 first unit pre-decoders ypdec12, 8 second unit pre-decoders ydec345, and 8 third unit pre-decoders ydec678.

The first unit pre-decoder ypdec12 in the first pre-decoder 15_1 decodes the inner column addresses byac_e<1:2> that are received from the column address controlling unit 10 to output the respective first decoding signals ya12<0>˜ya12<3>.

The second unit pre-decoder ydec345 in the first pre-decoder 15_1 decodes the inner column addresses byac<3:5> that are received from the column address controlling unit 10 to output the respective second decoding signals ya345<0>˜ya345<7>.

The third unit pre-decoder ydec678 in the first pre-decoder 15_1 decodes the inner column addresses byac<6:8> that are received from the column address controlling unit 10 to output the respective third decoding signals ya678<0>˜ya678<7>.

The second pre-decoder 16_1 is formed as similar as the first pre-decoder 15_1 except that the first unit pre-decoder ypdec12 in the second pre-decoder 16_1 decodes the inner column addresses byac_o that are received from the column address controlling unit 10 to output the first decoding signals ya12<0>˜ya12<3>.

The first main decoder 15_2 includes 64 unit main decoders ydec4. The unit main decoder ydec4 is activated by selected one of the second decoding signals ya345<0>˜ya345<7>, the third decoding signals ya678<0>˜ya678<7> to decode the first decoding signals ya12<0>˜ya12<3> to output a 4-bit YI signal. Accordingly, from the 64 unit main decoders ydec4, 256 YI signals are outputted totally.

The inner column address signals y<0:11> that are outputted from the column address controlling unit 10 are not to be used currently in the pre-decoder but to be used depending on the output mode of the memory device. That is, in the case of x16, they are not used as described above but in the case of x8 or x4, they are used.

Further, control signals yistp, yistpz have opposite phases from each other, which make the first pre-decoder 15_1 and the second pre-decoder 16_1 operate, alternatively. The control signals are generated in synchronous to rising edge of an external clock in a period corresponding to the burst length when a read command or a write command is inputted.

On the other hands, the Y controlling unit 35, 36 for the bank1 31, 32 shown on the left side in FIG. 3 is formed as similar as the Y controlling unit 15, 16 for the bank0 11, 12 and it will be omitted for detailed description of it for the sake of simplicity.

FIG. 4 exemplifies a circuit diagram of the first unit pre-decoder ypdec12 in FIG. 3.

Referring to FIG. 4, the first unit pre-decoder ypdec12 is enabled by the control signal yistpz to activate the first decoding signal ya12<0> when the inner column addresses byac_e<1:2> are all high level. In FIG. 4, one of the 4 first unit decoders ypdec12 included in the first pre-decoder 15_1 is shown, and the others of the first unit decoders ypdec12 receive the respective inner column addresses byac_e<1:2> to output the respective first decoding signals ya12<1:3>.

FIG. 5 represents a circuit diagram of the second unit pre-decoder ydec345 in FIG. 3.

Referring to FIG. 5, the second unit pre-decoder ydec345 activates the second decoding signal ya345<0> to the high level when the inner column address byac<3:5> are all activated to the high level. In FIG. 5, one of the 8 second unit decoders ydec345 included in the first pre-decoder 15_1 is shown and the others of the second unit decoders ydec345 receive the respective inner column addresses byac<3:5> to output the respective second decoding signals ya345<1:7>.

FIG. 6 illustrates a circuit diagram of the third unit pre-decoder ydec678 in FIG. 3.

Referring to FIG. 6, the third unit pre-decoder ydec678 activates the third decoding signal ya678<0> to the high level when the inner column address byac<6:8> are all activated to the high level. In FIG. 6, one of the 8 third unit decoders ydec678 included in the first pre-decoder 15_1 is shown and the others of the third unit decoders ydec678 receive the respective inner column addresses byac<6:8> to output the respective third decoding signals ya678<1:7>.

FIG. 7 shows a circuit diagram of the unit main decoder ydec4 in FIG. 3.

Referring to FIG. 7, the unit main decoder ydec4 is activated by one of the output signals from the 8 second unit pre-decoders ydec345 and one of the output signals from the 8 third unit pre-decoders ydec678 to buffer the respective first decoding signals ya12<0:3> from the first unit pre-decoder ypdec12 to output the 4 YI signals yi<0:3>.

Only if MOS transistors MN1, MN2 are turned on by the first decoding signal ya345<0> and the second decoding signal ya678<0>, the first decoding signals ya12<0:3> in the high level are buffered to output the YI signals yi<0:3> that are activated to the high level. In the actual operation, only one of the 4 YI signals yi<0:3> is activated and the others of the YI signals are deactivated.

In FIG. 7, one of the 64 unit main decoders ydec4 included in each of the first main decoders 15_2, 16_2 is shown and the others of the unit main decoders ydec4 receive the respective first decoding signals ya345<0:7> to output the respective YI signals yi<4:256>.

As described above, the column addresses y<0:11> are decoded at the pre-decoder and, then, decoded at the main decoder again to be outputted to the bank.

As the performance of the memory device is developed, the memory device happens to have a number of banks for independently accessing data. Therefore, the memory device should include the Y controlling unit for decoding the column addresses for each bank and, in turn, include the pre-decoder and the main decoder for each bank.

However, such a repetitive circuitry takes so large area in lay-out, which leads highly integrate the memory device.

### SUMMARY OF THE INVENTION

It is, therefore, a primary object of the present invention to provide a semiconductor memory device having a number of banks, which reduces circuit area of a Y controlling unit for decoding a column address.

In accordance with the present invention, there is provided a semiconductor memory device1, which includes a first bank and a second bank; a pre-decoder for pre-decoding a column address; a first main decoder for decoding the output signal from the pre-decoder to select a bit line of the first bank; and a second main decoder for decoding the output signal from the pre-decoder to select a bit line of the second bank.

In accordance with the present invention, there is provided a semiconductor memory device, which includes a first bank and a second bank; a pre-decoder for pre-decoding a column address to output one of a first pre-decoding signal and a second pre-decoding signal in response to a bank selecting signal for selecting one of the first bank and the second bank; a first main decoder for decoding the first pre-decoding signal to select a bit line of the first bank; and a second main decoder for decoding the second pre-decoding signal to select a bit line of the second bank.

In accordance with the present invention, there is provided 4. A semiconductor memory device, which includes a first bank and a second bank; a pre-decoder for pre-decoding a column address to output a pre-decoding signal; a first main decoder for decoding the pre-decoding signal to select a bit line of the first bank; and a second main decoder for decoding the pre-decoding signal to select a bit line of the second bank.

### BRIEF DESCRIPTION OF THE DRAWINGS

The above and other objects and features of the present invention will become apparent from the following description of preferred embodiments given in conjunction with the accompanying drawings, in which:

FIGS. 1 and 2 provide block diagrams of a semiconductor memory device having four banks;

FIG. 3 describes a block diagram of Y controlling units for a bank bank0 and a bank bank1;

FIG. 4 exemplifies a circuit diagram of a first unit pre-decoder shown in FIG. 3;

FIG. 5 represents a circuit diagram of a second unit pre-decoder shown in FIG. 3;

FIG. 6 illustrates a circuit diagram of a third unit pre-decoder shown in FIG. 3;

FIG. 7 shows a circuit diagram of a unit main decoder shown in FIG. 3;

FIG. 8 offers a block diagram of a semiconductor memory device in accordance with one embodiment of the present invention;

FIG. 9 provides a detailed block diagram of a semiconductor memory device shown in FIG. 8;

FIG. 10 shows a circuit diagram of a first unit pre-decoder shown in FIG. 9;

FIG. 11 represents a circuit diagram of a second unit pre-decoder shown in FIG. 9;

FIG. 12 illustrates a circuit diagram of a third unit pre-decoder shown in FIG. 9;

FIG. 13 represents a block diagram of a semiconductor memory device in accordance with a second embodiment of the present invention;

FIG. 14 exemplifies a circuit diagram of a first unit pre-decoder shown in FIG. 13;

FIG. 15 represents a circuit diagram of a second unit pre-decoder shown in FIG. 13;

FIG. 16 illustrates a circuit diagram of a third unit pre-decoder shown in FIG. 13; and

FIG. 17 shows a circuit diagram of a unit main decoder shown in FIG. 13.

### DETAILED DESCRIPTION OF THE PREFERRED EMBODIMENTS

Hereinafter, with reference to the accompanying drawings, a preferred embodiment of the present invention will be explained in detail.

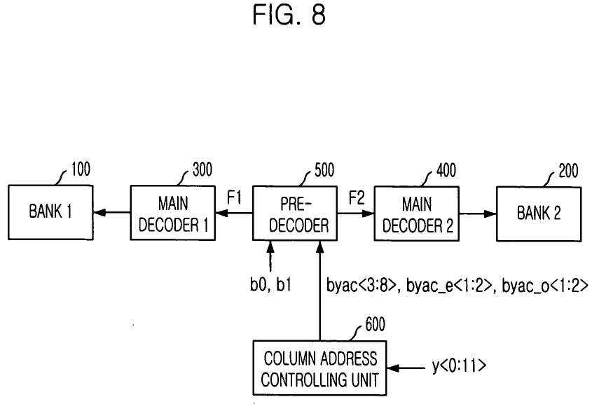

FIG. 8 offers a block diagram of a semiconductor memory device in accordance with one embodiment of the present invention.

Referring to FIG. 8, the semiconductor memory device according to the embodiment of the present invention comprises a first bank 100, a second bank 200, a pre-decoder 500 for outputting one of a first pre-decoding signal F1 and a second pre-decoding signal F2 in response to a bank selecting signal b0, b1 for selecting one of the first bank 100 and the second bank 200, a first main decoder 300 for decoding the first pre-decoding signal F1 from the pre-decoder 500 to select a bit line of the first-bank 100, and a second main decoder 400 for decoding the second pre-decoding signal F2 from the pre-decoder 500 to select a bit line of the second bank 200.

Further, the semiconductor memory device comprises a column address controlling unit 600 for adjusting inputted column addresses y<0:11> to inner column addresses byac<3:8>, byac_e<1:2>, byac_o<1:2> corresponding to a data output option, e.g., one of x16, x8 and x4 modes, to output to the pre-decoder 500.

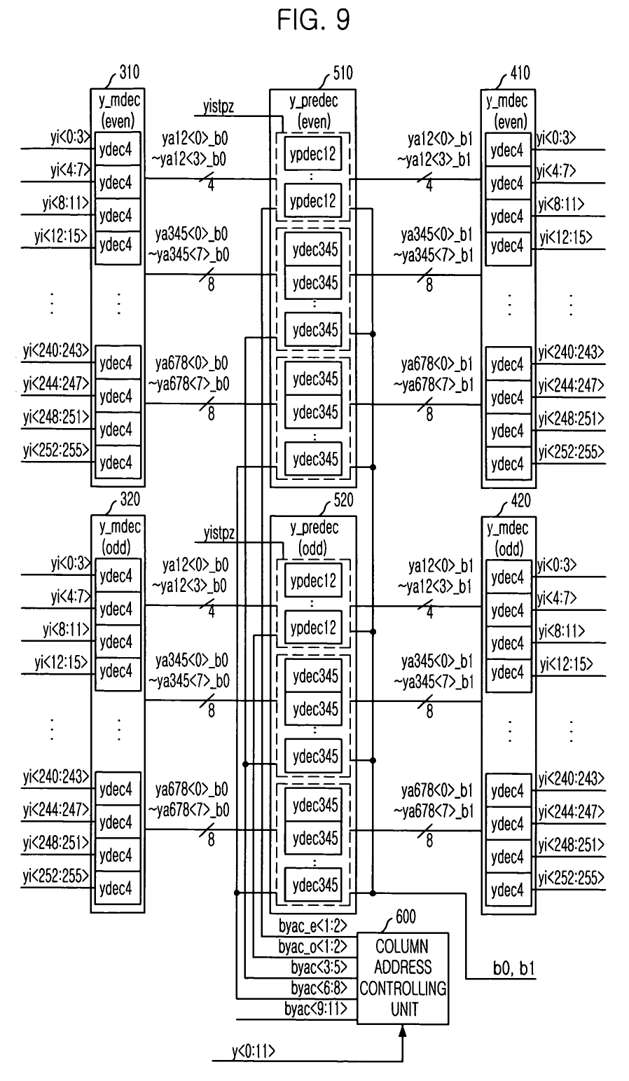

FIG. 9 provides a detailed block diagram of the semiconductor memory device in FIG. 8. Particularly, in FIG. 9, a bank0 and a bank 1 in a DDR memory device are shown.

In the DDR memory device, because an even data and an odd data are simultaneously outputted in one data access, each bank is divided into two regions and respective pre-decoders 510, 520 and respective main decoders 310, 320, 410, 420 are included in the memory device. The pre-decoder 520 for the odd data is formed as similar as the pre-decoder 510 for the even data and it will be described only for the pre-decoder 510 for the even data.

As shown in FIG. 9, the most outstanding feature of a Y controlling unit in the memory device of this embodiment is that the pre-decoders 510, 520 are used for both of the bank0 and the bank1 while the main decoders are included for the respective banks.

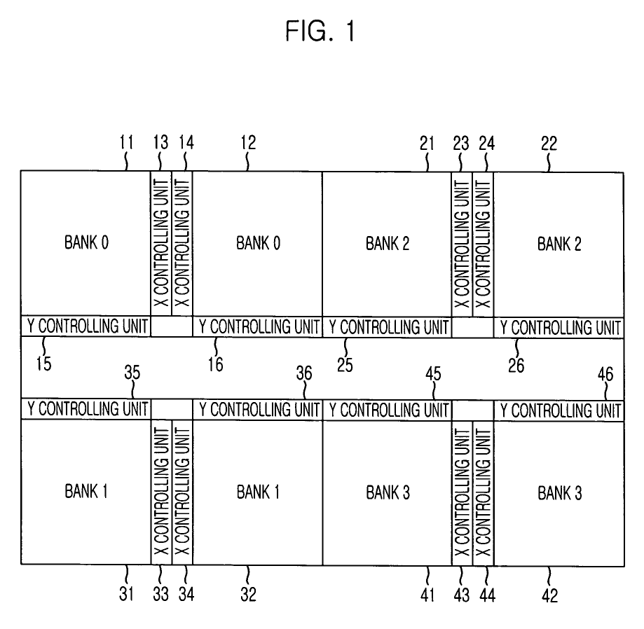

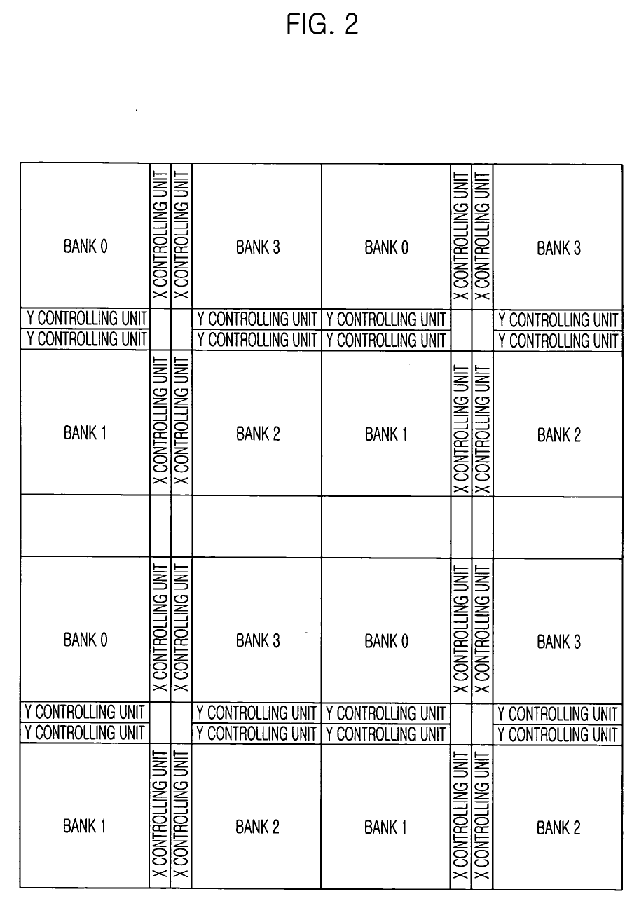

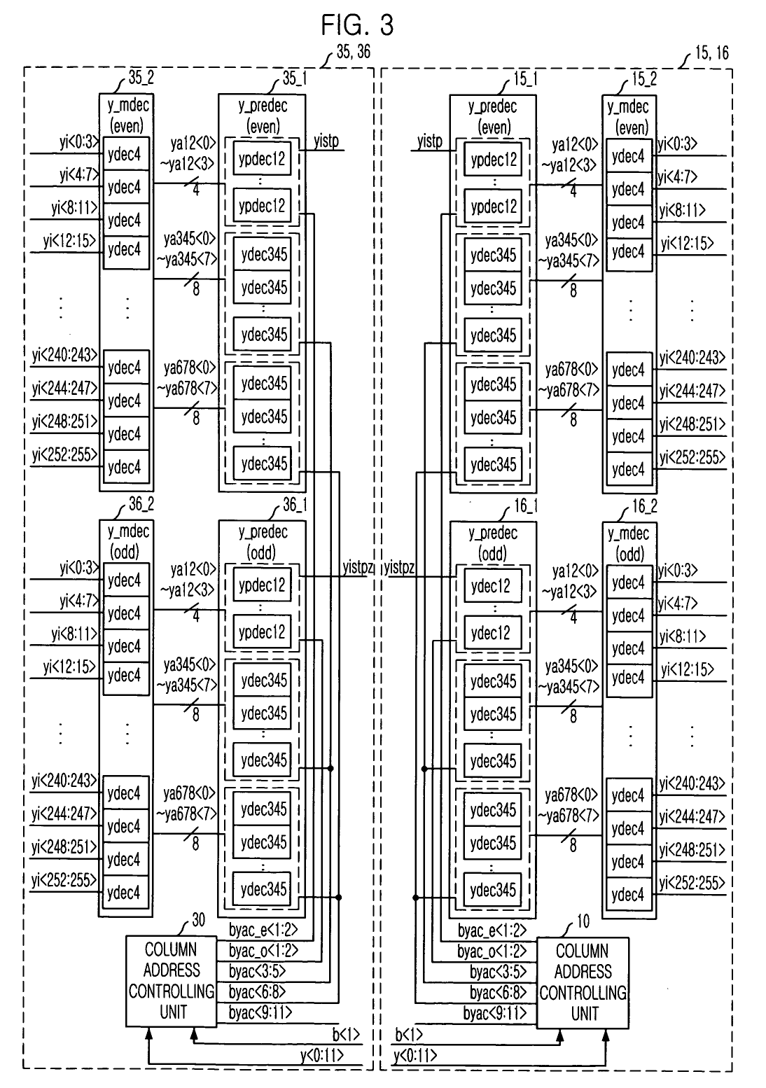

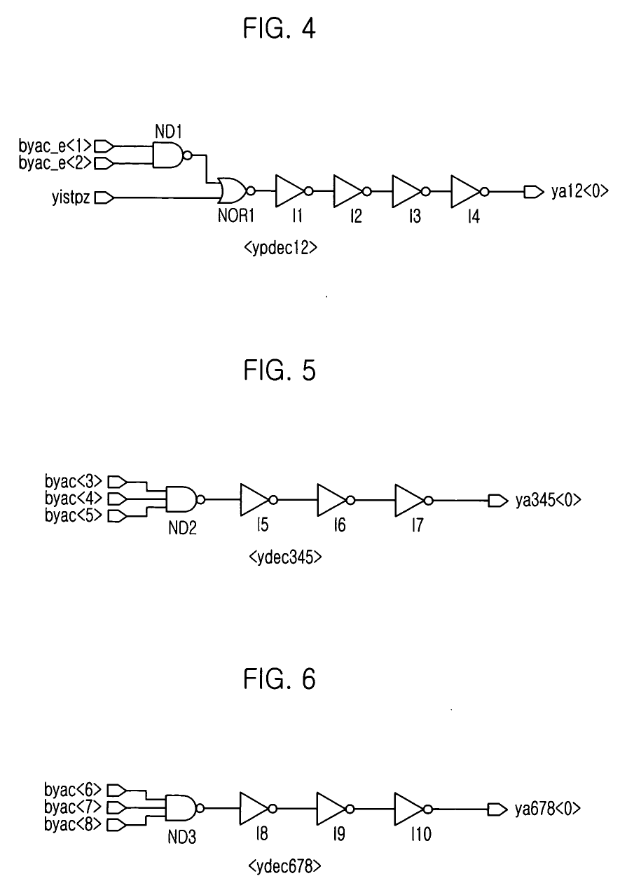

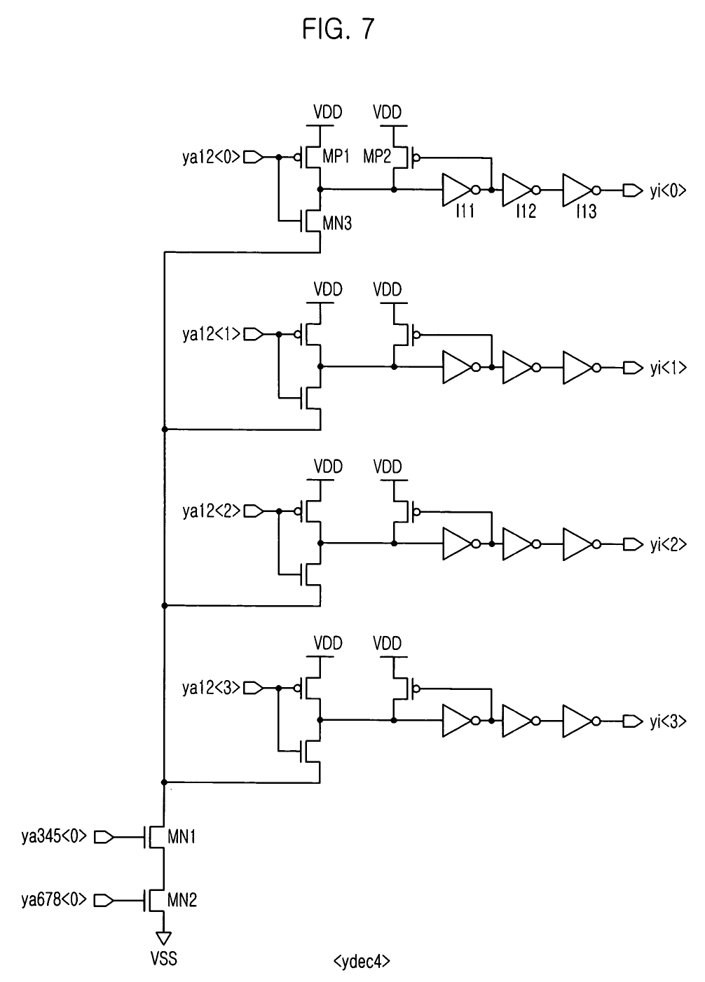

In the case of 12-bit column address y<0:11>, each of the pre-decoders 510, 520 includes 4 first unit pre-decoders ypdec12, 8 second unit pre-decoders ydec345, and 8 third unit pre-decoders ydec678. The function of each unit pre-decoder is as similar as that of the memory device as shown in FIG. 1.

On the other hand, through the inner column address byac<9:11> from the column address controlling unit is described as not used, it just shows the case of the x16 data output mode. In the case of the x8 or x4 data output mode, the inner column address byac<9:11> is also used for internal decoding.

FIG. 10 shows a circuit diagram of the first unit pre-decoder ypdec12 in FIG. 9.

Referring to FIG. 10, the first unit pre-decoder ypdec12 is enabled by a control signal yistpz to activate the first decoding signals ya12<0>_b0, ya12<0>_b1 to a high level when the inputted inner addresses byac_e<1:2> are all the high level.

At that point, if the first bank signal b0 that is activated to the high level is inputted, the first decoding signal ya12<0>_b0 for the bank0 is activated to the high level. On the contrary, if the second bank signal b1 that is activated to the high level is inputted, the first decoding signal ya12<0>_b1 is activated to the high level.

In FIG. 10, one of the 4 first unit pre-decoders ypdec12 that are included in the first pre-decoders 510 is shown. The others of the first unit pre-decoders ypdec12 receive the respective inner column addresses byac_e<1:2> to output the respective first decoding signals ya12<1:3>_b0, ya12<1:3>_b1.

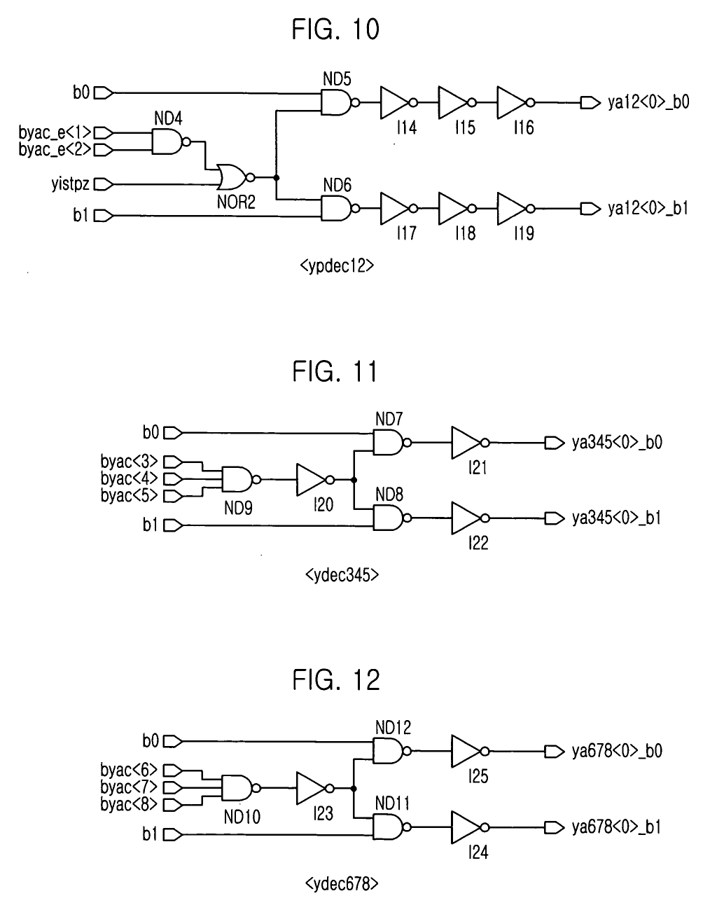

FIG. 11 represents a circuit diagram of the second unit pre-decoder ydec345 in FIG. 9.

Referring to FIG. 11, the second unit pre-decoder ydec345 activates the second decoding signals ya345<0>_b0, ya345<0>_b1 to the high level when the inputted inner column addresses byac<3:5> are all activated to the high level.

At that point, if the first bank signal b0 that is activated to the high level is inputted, the second decoding signal ya345<0>_b0 for the bank0 is activated to the high level. On the contrary, if the second bank signal b1 that is activated to the high level is inputted, the second decoding signal ya345<0>_b1 is activated to the high level.

In FIG. 1, one of the 8 second unit pre-decoders ydec345 that are included in the first pre-decoders 510 is shown. The others of the second unit pre-decoders ydec345 receive the respective inner column addresses byac<3:5> to output the respective second decoding signals ya345<1:7>_b0, ya345<1:7>_b1.

FIG. 12 illustrates a circuit diagram of the third unit pre-decoder ydec678 in FIG. 9.

Referring to FIG. 12, the third unit pre-decoder ydec678 activates the third decoding signal ya678<0>_b0, ya678<0>_b1 to the high level when the inputted inner column addresses byac<6:8> are all activated to the high level.

At that point, if the first bank signal b0 that is activated to the high level is inputted, the third decoding signal ya678<0>_b0 for the bank0 is activated to the high level. On the contrary, if the second bank signal b1 that is activated to the high level is inputted, the third decoding signal ya678<0>_b1 is activated to the high level.

In FIG. 12, one of the 8 third unit pre-decoders ydec678 that are included in the first pre-decoders 510 is shown. The others of the third unit pre-decoders ydec678 receive the respective inner column addresses byac<6:8> to output the respective third decoding signals ya678<1:7>_b0, ya678<1:7>_b1.

As described above, in the memory device according to this embodiment, the Y controlling units for controlling the bank0 and the bank1 includes the main decoders corresponding to the respective banks and the pre-decoder shared by both of the banks selectively in response to the bank signal so that the circuit area for the Y controlling unit can be reduced significantly. As the circuit area for the Y controlling unit is reduced, the circuit area of the entire memory device is, accordingly, reduced so as to increase the number of dies per wafer, which improves productivity.

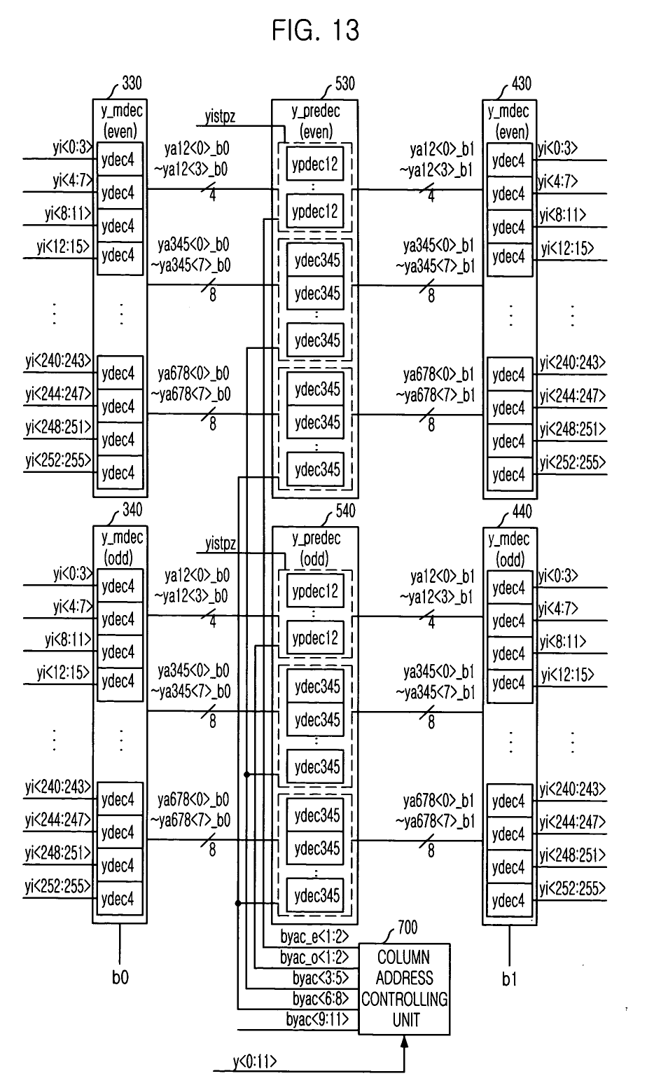

FIG. 13 represents a block diagram of a semiconductor memory device in accordance with a second embodiment of the present invention.

Referring to FIG. 13, the semiconductor memory device of the second embodiment comprises a first bank (not shown), a second bank (not shown), pre-decoders 530, 540 for pre-decoding column addresses to output pre-decoding signals ya12<0:3>, ya345<0:7>, yz678<0:7>, first main decoders 330, 340 for decoding the pre-decoding signals ya12<0:3>, ya345<0:7>, yz678<0:7> in response to the a first bank selecting signal b0 for selecting the first bank, to select a bit line of the first bank, and second main decoders 430, 440 for decoding the pre-decoding signals ya12<0:3>, ya345<0:7>, yz678<0:7> in response to the a second bank selecting signal b1 for selecting the second bank, to select a bit line of the second bank.

Further, the memory device of the second embodiment comprises a column controlling unit 700 for adjusting the column addresses to the inner column addresses corresponding to one of data output modes, e.g., x16, x8 and x4 modes, of the memory device to output to the pre-decoders 530, 540.

In the memory device of the second embodiment, the Y controlling unit for the bank0 and the bank1 includes the pre-decoders 510, 520 shared by both of the bank0 and the bank1 and the main decoders used for the respective banks.

In the memory device of the second embodiment, the pre-decoders 530, 540 output the same decoding signals while the main decoders 330, 340, 430, 440 corresponding to the respective banks are operated depending on the bank signals b0, b1. Therefore, the unit main decoders ydec4 in the main decoders of the memory device according to the second embodiment receive the bank selecting signals for bank selection.

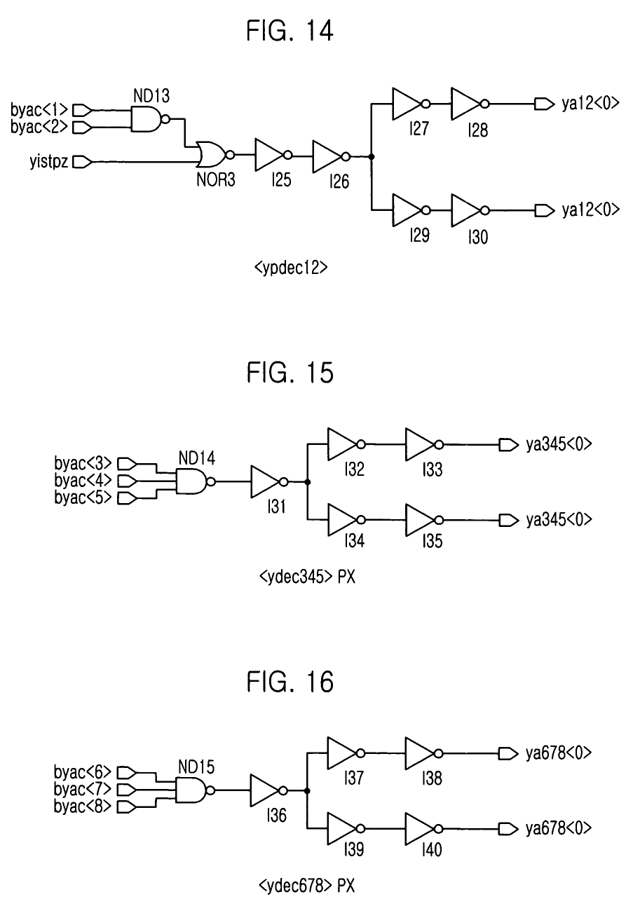

FIG. 14 exemplifies a circuit diagram of the first unit pre-decoder ypdec12 in FIG. 13.

Referring to FIG. 14, the circuit of the first unit pre-decoder ypdec12 is formed to be enabled by a control signal yistpz to activate the first decoding signal ya12<0> when the inner column addresses byac_e<1:2> are all activated to the high level. In FIG. 14, one of the 4 first unit decoders ypdec12 that are included in the pre-decoders 530 is shown. The others of the first unit pre-decoders ypdec12 receive the respective inner column addresses byac_e<1:2> to output the respective first decoding signals ya12<1:3>.

Because the first decoding signal ya12<0> is outputted both of the main decoder 330 for the bank0 and the main decoder 430 for the bank1, two buffers I27, I28, I29, I30 for increasing driving ability of the first decoding signal ya12<0> are included at the output stage.

FIG. 15 represents a circuit diagram of the second unit pre-decoder ydec345 in FIG. 13.

Referring to FIG. 15, the second unit pre-decoder ydec345 is formed to activate the second decoding signal ya345<0> to the high level when the inner column addresses byac<3:5> are all activated to the high level. In FIG. 15, one of the 8 second unit pre-decoders ydec345 that are included in the first pre-decoders 530 is shown. The others of the second unit pre-decoders ydec345 receive the respective inner column addresses byac<3:5> to output the respective second decoding signals ya345<1:7>.

Because the second decoding signal ya345<0> is outputted both of the main decoder 330 for the bank0 and the main decoder 430 for the bank1, two buffers I32, I33, I34, I35 for increasing driving ability of the second decoding signal ya345<0> are included at the output stage.

FIG. 16 illustrates a circuit diagram of the third unit pre-decoder ydec678 in FIG. 13.

Referring to FIG. 16, the third unit pre-decoder ydec678 is formed to activate the third decoding signal ya678<0> to the high level when the inner column addresses byac<6:8> are all activated to the high level. In FIG. 16, one of the 8 third unit pre-decoders ydec678 that are included in the first pre-decoders 530 is shown. The others of the third unit pre-decoders ydec678 receive the respective inner column addresses byac<6:8> to output the respective third decoding signals ya678<1:7>.

Because the third decoding signal ya678<0> is outputted both of the main decoder 330 for the bank0 and the main decoder 430 for the bank1, two buffers I37, I38, I39, I40 for increasing driving ability of the third decoding signal ya678<0> are included at the output stage.

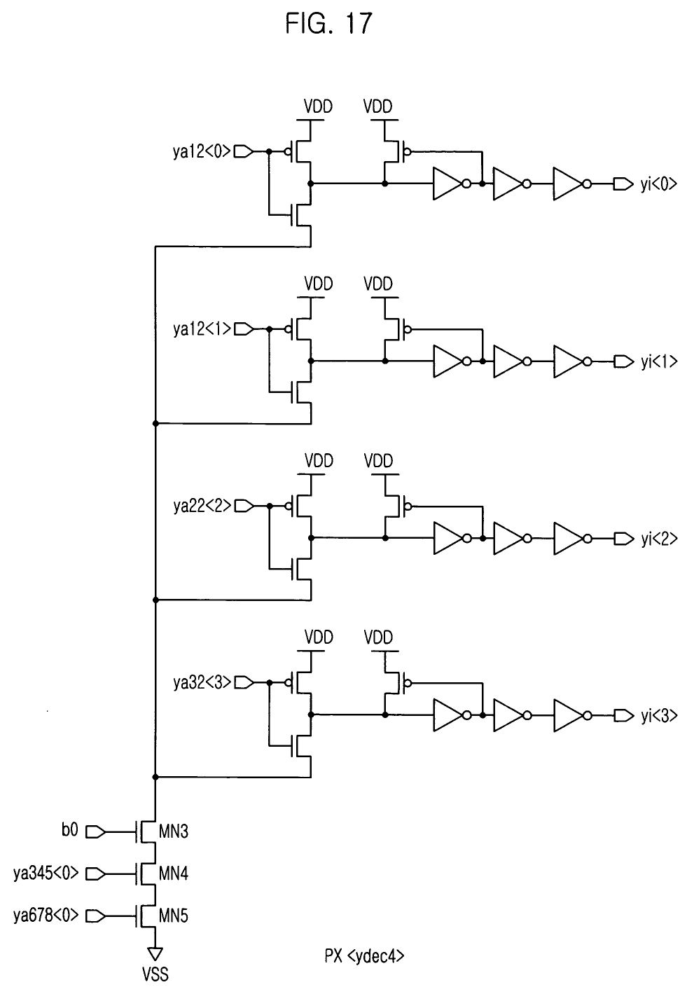

FIG. 17 shows a circuit diagram of the unit main decoder ydec4 in FIG. 13.

Referring to FIG. 17, the unit main decoder ydec4 is activated by the output signal from one of the 8 second unit pre-decoders ydec345, e.g., ya345<0>, the output signal from one of the 8 third unit pre-decoders ydec678, e.g, ya678<0>, and the bank selecting signal b0, for buffering the first decoding signals ya12<0:3> from the first unit pre-decoder ydec12 to output 4 activated YI signals yi<0:3>.

Further, in FIG. 17, one of the 64 unit main decoders ydec4 that are included in the main decoders 330 is shown. The others of the unit main decoders ydec4 receive the respective first decoding signals ya345<0:7> and the respective second decoding signals ya678<0:7>> to output the respective YI signals yi<4:256>.

Accordingly, the 64 main decoders ydec4 that are included in the main decoder 330 corresponding to the bank0 are formed to be activated by the bank selecting signal b0, respectively. On the other, the 64 main decoders ydec4 that are included in the main decoder 430 corresponding to the bank1 are formed to be activated by the bank selecting signal b1, respectively.

Because each of the main decoders is activated with the corresponding bank selecting signal, the same decoding signals from the pre-decoders can be inputted to both of the main decoders 330, 430.

As described above, in the memory device of the second embodiment, the Y controlling unit for controlling the bank 0 and the bank1 is formed to have the main decoders corresponding to the respective banks and the pre-decoders shared by the two banks. That is, by selectively using the pre-decoders depending on the bank selecting signals, the circuit area for the Y controlling unit can be significantly reduced. As the circuit area for the Y controlling unit is reduced, the circuit area of the entire memory device is, accordingly, reduced so as to increase the number of dies per wafer, which improves productivity.

According to the present invention, the circuit area for a circuit block for decoding the column address in the memory device can be significantly reduced so that the memory device can be integrated even highly. By integrating the memory device even highly, the number of the dies per wafer is increased to have improved productivity.

The present application contains subject matter related to Korean patent application No. 2003-98498, filed in the Korean Patent Office on Dec. 29, 2003, the entire contents of which being incorporated herein by reference.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

1. A semiconductor memory device comprising:
a first bank and a second bank;
pre-decoding means for pre-decoding a column address;
first main decoding means for decoding the output signal from the pre-decoding means to select a bit line of the first bank; and
second main decoding means for decoding the output signal from the pre-decoding means to select a bit line of the second bank.

2. A semiconductor memory device comprising:
a first bank and a second bank;
pre-decoding means for pre-decoding a column address to output one of a first pre-decoding signal and a second pre-decoding signal in response to a bank selecting signal for selecting one of the first bank and the second bank;
first main decoding means for decoding the first pre-decoding signal to select a bit line of the first bank; and
second main decoding means for decoding the second pre-decoding signal to select a bit line of the second bank.

3. The semiconductor memory device of claim 2, further comprising column address controlling means for adjusting the inputted column address into an inner column address corresponding to a data output option (one of x16, x8, x4 modes) of the memory device, to output the inner address to the pre-decoding means.

4. A semiconductor memory device comprising:
a first bank and a second bank;
pre-decoding means for pre-decoding a column address to output a pre-decoding signal;
first main decoding means for decoding the pre-decoding signal to select a bit line of the first bank; and
second main decoding means for decoding the pre-decoding signal to select a bit line of the second bank.

5. The semiconductor memory device of claim 4, further comprising column address controlling means for adjusting the inputted column address into an inner column address corresponding to a data output option (one of x16, x8, x4 modes) of the memory device, to output the inner address to the pre-decoding means.
